(19) United States
(12) Patent Application Publication
(10) Pub. No.: US 2023/0309215 A1
(43) Pub. Date: Sep. 28, 2023

(54) PRINTED CIRCUIT BOARD TO PRINTED CIRCUIT BOARD RADIO FREQUENCY INTERFACE

(71) Applicant: Telefonaktiebolaget LM Ericsson (publ), Stockholm (SE)

(72) Inventors: Marthinus DA SILVERIA, OTTAWA (CA); Neil McGOWAN, STITTSVILLE (CA)

(21) Appl. No.: 18/022,876

(22) PCT Filed: Sep. 3, 2020
(86) PCT No.: PCT/IB2020/058211

§ 371 Date: Feb. 23, 2023

(51) Int. Cl. H05K 1/02; H05K 1/14; H05K 1/11

(52) U.S. Cl. CPC H05K 1/0239; H05K 1/144; H05K 1/115; H05K 2201/041

(57) ABSTRACT

A radio frequency (RF) coupler is configured to carry RF signals from a first printed circuit board (PCB) to a second PCB. The RF coupler includes a first trace on an outer surface of the first PCB and a second trace on an outer surface of the second PCB. The first trace and the second trace at least partially overlap to form an RF broadside coupler when the first PCB is positioned adjacent the second PCB. Each of the first trace and the second trace are covered by respective dielectric coatings such that a direct current (DC) electrical connection between the first trace and the second trace is prevented when the first PCB is positioned adjacent the second PCB.

### TECHNICAL FIELD

Printed circuit boards in general, and in particular to transmission line trace couplers for printed circuit boards.

### BACKGROUND

Traditional radio frequency (RF) connections between printed circuit boards (PCBs) are generally accomplished using RF connectors or soldered coax structures. However, when dealing with RF frequency signals, high quality, low passive intermodulation (PIM) connectors that are sufficient for required power levels are typically large, costly, and/or are difficult to use, not reliable or not available.

Soldered ground connections may be used as an alternative but can be difficult to reliably produce due to the high thermal conductivity of the materials that need to be soldered. If the soldering is not properly done, cold solder joints can lead to PIM problems. Further, some types of soldered connections may be difficult to disengage.

### SUMMARY

According to one aspect of the disclosure, a radio frequency, RF, coupler is configured to carry RF signals from a first printed circuit board, PCB, to a second PCB. The RF coupler comprises a first trace on an outer surface of the first PCB and a second trace on an outer surface of the second PCB. The first trace and the second trace at least partially overlap to form an RF broadside coupler when the first PCB is positioned adjacent the second PCB. Each of the first trace and the second trace are covered by respective dielectric coatings such that a direct current, DC, electrical connection between the first trace and the second trace is prevented when the first PCB is positioned adjacent the second PCB.

According to one or more embodiments of this aspect, the first PCB has a multi-layer structure including at least three metal layers and at least two dielectric layers, and the first PCB further comprises a first ground plane on the outer surface of the first PCB, the first ground plane defining a metal-free window surrounding the first trace; and a second ground plane on a second metal layer of the first PCB. The second ground plane extends over the metal-free window of the first ground plane and is separated from the first trace by at least two of the dielectric layers of the first PCB. According to one or more embodiments of this aspect, the second metal layer of the first PCB is a second outer surface of first PCB. According to one or more embodiments of this aspect, the first PCB further comprises a plurality of vias connecting the first and second ground planes in a region surrounding the metal-free window of the first ground plane. According to one or more embodiments of this aspect, the first PCB further comprises at least one windowed ground plane on a metal layer between the first and second ground planes, the at least one windowed ground plane having a metal-free window that is coextensive with the metal free window of the first ground plane. According to one or more embodiments of this aspect, the plurality of vias are further connected to the at least one windowed ground plane between the first and second ground planes.

According to one or more embodiments of this aspect, the second PCB has a multi-layer structure including at least three metal layers and at least two dielectric layers, and the second PCB further comprises a third ground plane on the outer surface of the second PCB, the third ground plane defining a metal-free window surrounding the second trace, and a fourth ground plane on a second metal layer of the second PCB. The fourth ground plane extends over the metal-free window of the third ground plane and is separated from the second trace by at least two of the dielectric layers of the second PCB. According to one or more embodiments of this aspect, the second metal layer of the second PCB is a second outer surface of second PCB. According to one or more embodiments of this aspect, the second PCB further comprises a plurality of vias connecting the third and fourth ground planes in a region surrounding the metal-free window of the third ground plane. According to one or more embodiments of this aspect, the second PCB further comprises at least one windowed ground plane on a metal layer between the third and fourth ground planes, the at least one windowed ground plane having a metal-free window that is coextensive with the metal free window of the third ground plane. According to one or more embodiments of this aspect, the plurality of vias are further connected to the at least one windowed ground plane between the third and fourth ground planes.

According to one or more embodiments of this aspect, a width of the first trace is selected based at least in part on a desired impedance of the RF broadside coupler. According to one or more embodiments of this aspect, in an overlap area between the first trace and the second trace, a width of the second trace is less than the width of the first trace. According to one or more embodiments of this aspect, a difference between respective widths of the first and second traces determines a positioning tolerance of the first PCB and the second PCB. According to one or more embodiments of this aspect, a length of an overlap area between the first trace and the second trace is selected based on desired performance criteria of the RF broadside coupler. According to one or more embodiments of this aspect, the desired performance criteria of the RF broadside coupler comprises at least one of insertion loss and return loss over a frequency range of interest.

### BRIEF DESCRIPTION OF THE DRAWINGS

A more complete understanding of the present embodiments, and the attendant advantages and features thereof, will be more readily understood by reference to the following detailed description when considered in conjunction with the accompanying drawings wherein:

FIGS. 1A-C are diagrams of an RF coupler according to some embodiments of the present disclosure, wherein FIG. 1A is a cross-sectional view of the RF coupler;

FIG. 1B is an expanded view of layers L5 and L6 of the RF coupler of FIG. 1A; and

FIG. 1C is an isometric view showing coupled transmission line traces on layers L5 and L6;

FIG. 2 is an illustration of an example RF coupler according to some embodiments of the present invention;

FIG. 3 is an isometric view of an example RF coupler according to some embodiments of the present disclosure;

FIG. 4 is a top view of the RF coupler of FIG. 3; and

FIGS. 5-10 are top views of metal layers of the RF coupler of FIGS. 3 and 4.

### DETAILED DESCRIPTION

Embodiments as described herein may be used to connect a RF transmission line trace on one PCB to an RF transmission line trace on another PCB using a broadside transmission line trace coupler with low PIM, insertion loss and return loss. The coupler may also be designed to handle specified mechanical tolerances. While applicable to many fields, some embodiments may be applicable to use in 3rd Generation Partnership Project (3GPP) 5th Generation (5G) (also referred to as New Radio (NR)) advanced antenna Systems (AAS) applications.

Embodiments disclosed may have one or more of the following advantages with respect to the problems discussed herein.
1) There may be no soldering required between PCBs
2) Very low PIM may be achieved (as compared with other PCB coupling solutions) which is relevant for frequency division duplex (FDD) applications
3) The capacitive coupling of the ground around the broadside coupled line reduces energy leakage.

Before describing in detail example embodiments, it is noted that the embodiments reside primarily in combinations of apparatus components and processing steps related to RF coupling a RF transmission line trace or trace from a first PCB to a RF transmission line trace or trace of a second PCB. Accordingly, components have been represented where appropriate by conventional symbols in the drawings, showing only those specific details that are pertinent to understanding the embodiments so as not to obscure the disclosure with details that will be readily apparent to those of ordinary skill in the art having the benefit of the description herein. Like numbers refer to like elements throughout the description.

As used herein, relational terms, such as “first” and “second,” “top” and “bottom,” and the like, may be used solely to distinguish one entity or element from another entity or element without necessarily requiring or implying any physical or logical relationship or order between such entities or elements. The terminology used herein is for the purpose of describing particular embodiments only and is not intended to be limiting of the concepts described herein. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

In embodiments described herein, the joining term, “in communication with” and the like, may be used to indicate electrical or data communication, which may be accomplished by physical contact, induction, electromagnetic radiation, radio signaling, infrared signaling or optical signaling, for example. One having ordinary skill in the art will appreciate that multiple components may interoperate and modifications and variations are possible of achieving the electrical and data communication.

In some embodiments described herein, the term “coupled,” “connected,” and the like, may be used herein to indicate a connection, although not necessarily directly, and may include wired and/or wireless connections.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Of note, the terms “line trace,” “transmission line trace” and “strip line trace” are used interchangeably throughout this disclosure.

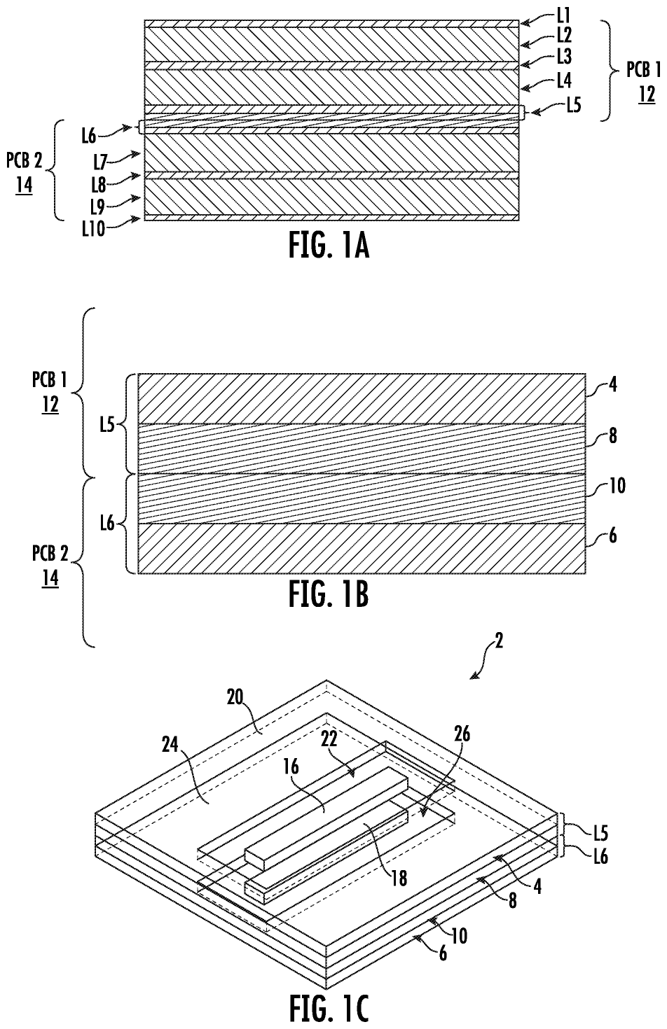

Referring now to the drawing figures, in which like elements are referred to by like reference numerals, there is shown in FIGS. 1A-1C a schematic diagram of an RF coupler 2 according to some embodiments of the present disclosure. FIGS. 1A-1C illustrate an example embodiment in which the RF coupler 2 is configured to couple RF signals between transmission line traces on a pair of printed circuit boards (PCBs), identified as PCB1 12 and PCB2 14. As may be seen in FIG. 1A, PCB1 12 has a multi-layer structure composed of metal layers L1, L3 and L5, and dielectric layers L2 and L4. As will be described in further detail below, metal layers L1, L3 and L5 are commonly formed of a metal (such as copper, silver gold etc.) but more generally may be composed of any suitable electrically conductive material. The metal layers may be used to form electrically conductive structures (such as ground planes, transmission line traces, and distributed devices for example) and these structures may be connected together, through dielectric layers L2 and L4, by means of vias (not shown in FIGS. 1A-1C). Dielectric layers L2 and L4 may be composed of any suitable dielectric material (such as glass, fiber, reinforced, plastic) to provide electrical isolation between adjacent metal layers and to provide structural support for the PCB1 12. In embodiments of the present disclosure, PCB1 12 may comprise two or more metal layers and one or more dielectric layers. For simplicity of illustration and explanation, PCB1 12 is shown as a five-layer structure comprising three metal layers (L1, L3 and L5) and two dielectric layers (L2 and L4). However, PCB structures having more layers may be used in various embodiments.

As may also be seen in FIG. 1A, PCB2 14 has a multi-layer structure composed of metal layers L6, L8 and L10, and dielectric layers L7 and L9. As will be described in further detail below, metal layers L6, L8 and L10 are commonly formed of a metal (such as copper, silver gold etc.) but more generally may be composed of any suitable electrically conductive material. The metal layers may be used to form electrically conductive structures such as ground planes and transmission line traces, and these structures may be connected together, through dielectric layers L7 and L9, by means of vias (not shown in FIGS. 1A-1C). Dielectric layers L7 and L9 may be composed of any suitable dielectric material (such as glass, fiber, reinforced plastic, etc.) to provide electrical isolation between adjacent metal layers and to provide structural support for the PCB2 14. In embodiments of the present disclosure, PCB2 14 may comprise two or more metal layers and one or more dielectric layers. For simplicity of illustration and explanation, PCB2 14 is shown as a five-layer structure comprising three metal layers (L6, L8 and L10) and two dielectric layers (L7 and L9). However, PCB structures having more layers may be used.

Referring to FIG. 1B, in the illustrated embodiment each of metal layers L5 and L6 are composed of a respective conductive layer 4 and 6 and a respective dielectric coating 8 and 10. The conductive layers 4 and 6 may be composed of a metal (e.g. copper, silver, gold etc.) as described above. The dielectric coatings 8 and may be composed of solder mask, Polytetrafluoroethylene (PTFE), or other insulating materials, and provide a thin electrical barrier between the two metal layers 4 and 6.

Referring now to FIG. 1C, in accordance with embodiments of FIGS. 1A-1C, RF coupler 2 is provided by a first transmission line trace 16 in metal layer L5 of PCB1 12 and a second transmission line trace 18 in metal layer L6 of PCB2 14. It will be appreciated that the dielectric coatings 8 and 10 extending between the first and second transmission line traces 16 and 18 cooperate to allow efficient capacitive coupling between the two transmission line traces 16 and 18 while preventing a direct current (DC) connection, or an electrical short, between the two transmission line traces 16 and 18.

Also shown in FIG. 1C, is a ground plane 20 in metal layer L5 of PCB1 12. The L5 ground plane 20 surrounds the first transmission line trace 16, and is separated from the first transmission line trace 16 to define a metal-free window 22 that may be at least partially filled with dielectric material of the L5 dielectric coating 8. In cooperation with other ground planes on other layers of the PCB1 12, as will be described in greater detail below, the ground plane 20 aids to reduce RF signal leakage from two transmission line traces 16 and 18. In a corresponding manner, metal layer L6 of PCB2 14 also includes a ground plane 24 that surrounds the second transmission line trace 18 to define a metal-free window 26 that may be at least partially filled with dielectric material of the L5 dielectric coating 10. In cooperation with other ground planes on other layers of the PCB2 14, as will be described in greater detail below, the ground plane 24 aids to reduce RF signal leakage from the two transmission line traces 16 and 18.

The RF coupler 2 of FIGS. 1A-1C may provide a number of advantages over traditional RF connectors. For example, the RF coupler 2 requires no soldering between PCBs and provides exceptionally low PIM which is essential for FDD applications. Further, in some embodiments, capacitive coupling of the ground planes around the broadside coupled line reduces energy leakage.

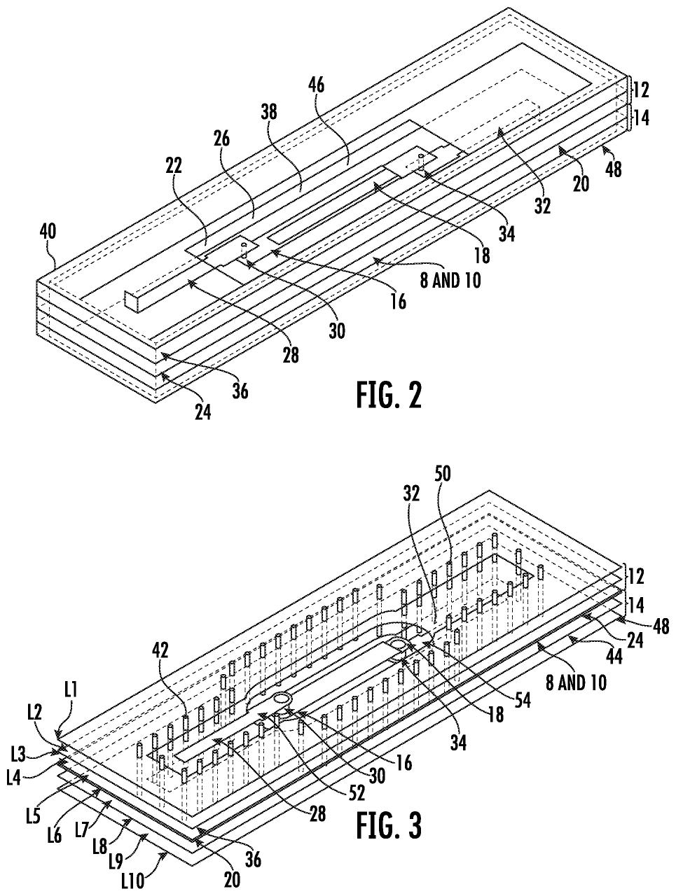

FIG. 2 is an illustration of an example RF coupler in accordance with some embodiments of the present invention. The embodiments of FIG. 2 include a first PCB1 12 positioned over a second PCB2 14, such that the first transmission line trace 16 in metal layer L5 of PCB1 12 and the second transmission line trace 18 in metal layer L6 of PCB2 14 are aligned, as shown in FIGS. 1A-1C. The first transmission line trace 16 may be connected to an RF transmission strip line 28 in layer L3 of PCB1 12, through an RF via 30. Similarly, the second transmission line trace 18 may be connected to an RF transmission strip line 32 in layer L8 of PCB2 14, through an RF via 34. The RF transmission strip lines 28 and 32 operate to conduct RF signals to and from the RF coupler, and may be configured for this purpose using methods well known in the art.

Metal layer L3 of PCB1 12 further includes a ground plane 36 having a metal-free window 38 that is co-extensive with the window 22 in layer L5. Metal layer L1 (i.e. the top layer) of PCB1 12 further includes a ground plane 40 that is configured to cover the windows 22 and 38 of layers L5 and L3. In some embodiments, as shown in FIG. 3, vias 42, through dielectric layers L2 and L4, form a “picket fence” of electrical connections between the ground planes 40, 36 and 20 on layers L1, L3 and L5 and surrounding the metal-free windows 22 and 38. The combination of windowed ground planes on Layers L3 and L5, solid ground plane 40 on L1, and vias 42 creates a chamber within PCB1 12 that operates to improve the performance of the RF coupler as will be described in greater detail below.

Metal layer L8 of PCB2 14 further includes a ground plane 44 having a metal-free window 46 that is co-extensive with the window 26 in layer L6. Metal layer L10 (i.e. the bottom layer) of PCB2 14 further includes a ground plane 48 that is configured to cover the windows 26 and 46 of layers L6 and L8. In some embodiments, vias 50, as shown in FIG. 3, through dielectric layers L7 and L9 form a “picket fence” of electrically connections between the ground planes 24, 44 and 48 on layers L6, L8 and L10 and surrounding the metal-free windows 26 and 46. The combination of windowed ground planes on Layers L6 and L8, solid ground plane 48 on L10, and vias 50 creates a chamber within PCB2 14 that improves the performance of the RF coupler.

As may be appreciated, when the two PCBs 12 and 14 are positioned adjacent to each other as shown in FIGS. 1A-1C and 2, the L5 and L6 ground planes 20 and 24 will be separated by dielectric coatings 8 and 10, which are relatively thin (compared to dielectric layers L2, L4, L7 and L9, for example). Due to the dielectric constant of the coatings 8 and 10, efficient capacitive coupling between the two ground planes 20 and 24 can be obtained. This capacitive coupling can be further increased by increasing the minimum width, w, of the L5 and L6 ground planes 20 and 24 in the vicinity of the metal-free windows 22 and 26 (see also FIGS. 7 and 8). For example, in some embodiments, a minimum width w of about 5 mm may be used for a 2 GHz coupler. Efficient capacitive coupling between the L5 and L6 ground planes 20 and 24 enables the respective chambers in PCB1 12 and PCB2 14 to cooperate to completely shield the RF coupler, thereby preventing leakage of RF signals from RF coupler 2. Importantly, this shielding effect is obtained even when the two PCBs 12 and 14 are imperfectly aligned. As a result, RF couplers constructed in accordance with embodiments of the present invention may tolerate much greater mechanical misalignment than prior art devices, without suffering significantly higher RF signal leakage.

In more general terms, each PCB 12 and 14 has a multi-layer structure including at least three (i.e. three or more) metal layers and at least two (i.e. two or more) dielectric layers. A first one of the outer surfaces of the PCB 12 and 14 comprises a transmission line trace of the RF coupler. This transmission line trace capacitively couples to a ground plane provided on a metal layer that separated from the transmission line trace by at least two dielectric layers of the PCBs 12 and 14. In the example embodiments of FIGS. 1A-C and 2, each PCB 12 and 14 has a multi-layer structure including three metal layers and two dielectric layers. In these embodiments, the transmission line trace of the RF coupler and its ground plane are located on opposite outer surfaces of the PCB 12 and 14. In an embodiment in which the PCB 12 or 14 has more than three metal layers (and more than two dielectric layers), the ground plane for the transmission line trace of the RF coupler 2 may be placed on an internal metal layer of the PCB 12 or 14, provided that there are at least two dielectric layers between the transmission line trace of the RF coupler and its ground plane.

The L5 trace 16 at the bottom of PCB1 12 is coupled to the L6 trace 18 at the top of PCB2 14 through dielectric coatings 8 and 10. The dielectric coatings 8 and 10 prevent any direct current (DC) from flowing between the traces 16 and 18, while at the same time improving capacitive coupling between the traces 16 and 18. When positioned in the manner illustrated, trace 16 and trace 18 form a high-performance broadside coupler that connects the two PCBs 12 and 14. The length of the RF coupler is determined by the length of the region of overlap between the two traces 16 and 18, and impacts the insertion and return loss of the RF coupler.

The shape and positioning of the first and second transmission line traces 16 and 18 in the broadside coupler design of FIGS. 1 and 2 maintain performance within a mechanical X-Y position tolerance between the PCBs 12 and 14. For example, it is well known that the impedance of a transmission line trace is determined by: the width of the transmission line; the thickness of the dielectric layer between the transmission line trace and the ground plane and the effective dielectric constant of the dielectric layer. The use of windowed ground planes on the internal metal layers of PCBs 12 and 14 means that the thickness of the dielectric 8 and 10 between the transmission line trace (e.g. the first transmission line trace 16) and the ground plane(s) 40 and 48 is equal to the combined thickness of dielectric layers L2 and L4 in PCB1 12, and layers L7 and L9 in PCB2 14. This means that, for a given impedance (such as 50 Ohms, for example) the width of the transmission line trace (e.g. the first transmission line trace 16) will be significantly wider than would be required without windowed ground planes 36 and 44 on the internal metal layers of the two PCBs 12 and 14. Importantly, the impedance of RF coupler 2 is dominated by the width of the widest transmission line trace 16 or 18. Consequently, the width of the first transmission line trace 16 may be selected to provide a desired impedance of the RF coupler 2, and the width of the second transmission line trace 18 can be made narrower without changing the coupler impedance. The difference between the respective widths of the first and second transmission line traces 16 and 18 determines the range of misalignment between the two PCBs 12 and 14 that can be tolerated without significantly affecting the impedance of the RF coupler 2. As a result, RF couplers constructed in accordance with various embodiments of the present invention can tolerate much greater mechanical misalignment than prior art devices, without suffering a change in impedance which would result in significantly higher insertion loss.

For example, in order to have a broadside coupler that has a good RF performance over a significant amount of mechanical tolerance, a coupler with a narrow line may be overlapped with a wider line. The larger the difference between the wide and narrow lines, the larger the mechanical tolerance that can be achieved. However, the narrow line should not be too narrow as the width of the narrow line will affect the return loss as well as the insertion loss. The wide line width may be determined by the distance to the ground above it and the distance to the ground below it, as well as the dielectric constant. The larger the distance, the wider the line has to be for a desired 50 ohm line impedance. The openings, i.e., ground clearances, metal-free windows, 22, 26, 38 and 46 allow the line 16 to be very wide as this line will have a large ground spacing above (L1 to L5) and below the line (L5 to L10). Lines 28 and 32 are narrower, as ground planes are closer to the lines. Line 28 has a ground plane on L1 above it and on L6 below it.

So, the open areas (ground clearances, metal-free windows) 22, 26, 38 and 46 allow for a wide line 16, and with a narrow line 18, good mechanical tolerances are achieved and as long as the lines overlap, performance should be good.

FIG. 3 is an isometric view of RF coupled printed circuit boards according to some embodiments of the present disclosure with via coupled ground planes. A first PCB1 12 is positioned on top of a second PCB2 14. PCB1 12 may be constructed from multiple layers (in the illustrated embodiments, five layers (L1-L5) are shown). PCB1 12 has a bottom ground plane 20 on L5. PCB1 12 also has an internal ground plane 36 on L3 and a top ground plane 40 on L1. The ground planes function to shield the transmission line traces of the PCBs 12 and 14. PCB1 12 has an RF strip line trace 28 on L3. PCB1 12 also has an RF strip line transition 52 on L3. A via 30 runs from RF strip line trace 28 on L3 to the first transmission line trace 16 on L5. The strip line traces 28 and 16, via 30 and strip line transition 52 carry RF signals on PCB1 12.

PCB2 14 may also be constructed from multiple layers (in the illustrated embodiments, five layers (-L6-L10) are shown). PCB2 14 has a top ground plane 24 on L6. PCB2 14 also has an internal ground plane 44 on L8 and a bottom ground plane 48 on L10. PCB2 14 has an RF strip line trace 32 and an RF strip line transition 54 on L8. A via 34 runs from RF strip line trace 32 on L8 to the second transmission line trace 18 on L6. The strip line traces 18 and 32, via 34 and strip line transition 54 carry RF signals on PCB2 14. Dielectric coatings 8 and 10 of PCB1 12 and PCB2 14 prevent any DC current from flowing between the first and second transmission line traces 16 and 18 and improve capacitive coupling between the traces 16 and 18 and ground planes 20 and 24.

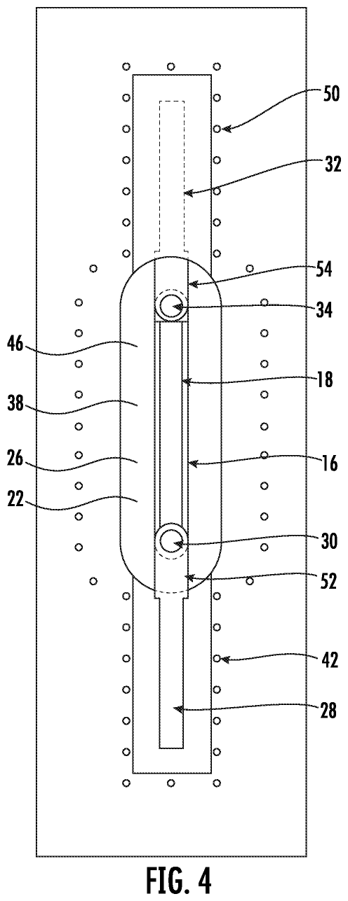

FIG. 4 is a top view of the RF coupled printed circuit boards of FIG. 3. As shown in FIG. 4, PCB2 14 has an RF strip line trace 32 on L8. Metal free windows, i.e., ground clearances 38 and 46 are respectively formed on L3 and L8. PCB2 14 also has an RF strip line transition 54 on L8. Metal free windows, i.e., ground clearances, 38, 22, 26 and 46 are respectively provided on L3, L5, L6 and L8. PCB2 14 has an RF strip line trace 18 on L6. A via connection 34 runs from the trace 18 on L6 to the trace 32 on L8. PCB1 12 has an RF strip line trace 28 on L3. PCB1 12 also has an RF strip line transition 52 on L3. PCB1 12 has an RF strip line trace 16 on L5. A via connection 30 runs from the trace 28 on L3 to the trace 16 on L5. Ground vias 42 and 50 are provided to electrically couple the ground planes.

A return current path is provided by the capacitive coupling of the ground planes 20 and 24. The current generates an electric field between the two ground planes 20 and 24 and the field then creates a current on the coupled ground plane. The coupling of the ground planes connects the “picket fence” of vias 42 on the first PCB1 12 to the “picket fence” vias 50 on the second PCB2 14 so that the windows 22, 26, 38 and 46 are closed to prevent RF leakage out of the coupler 2. Without the ground plane 20 and 24 coupling, RF energy may leak out of a gap between the two PCBs 12 and 14. A significant width of overlapping ground planes 20 and 24 should be provided to create the desired capacitive coupling. As an example, an overlapping width of 5 mm may be used for 2 GHz signal.

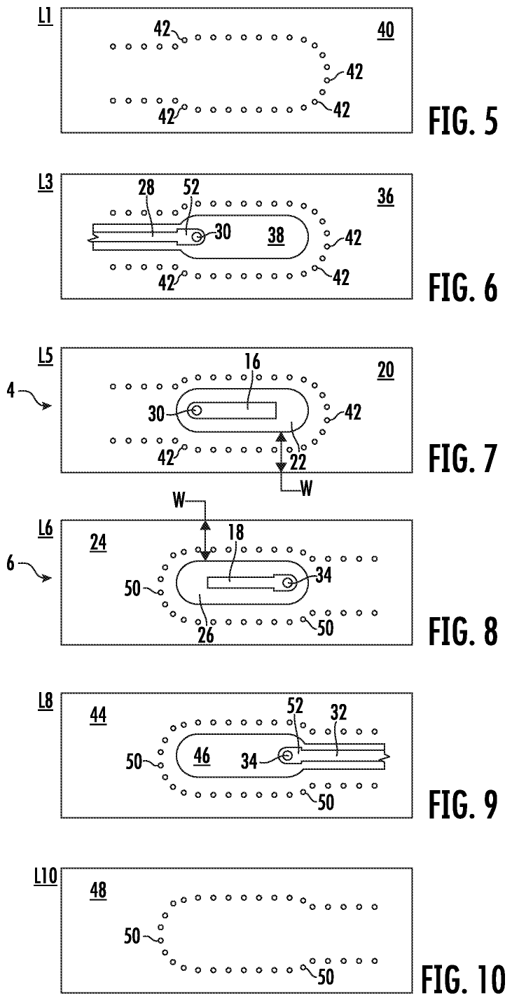

FIGS. 5-10 are top views of the metal layers (L1, L3, L5, L6, L8 and L10) of the RF coupled printed circuit boards 12 and 14 of FIG. 3. FIG. 5 is an illustration of L1, showing the solid (i.e. non-windowed) ground plane 40 and vias 42 connecting the ground plane 40 to the L3 ground plane 36. FIG. 6 is an illustration of L3, showing the windowed ground plane 36 and vias 42 connecting the ground plane 36 to the L1 ground plane 40 and the L5 ground plane 20. FIG. 7 is an illustration of L5, showing the windowed ground plane 20 and vias 42 connecting the ground plane 20 to the L3 ground plane 36. FIG. 8 is an illustration of L6, showing the windowed ground plane 24 and vias 50 connecting the ground plane 24 to the L8 ground plane 44. FIG. 9 is an illustration of L8, showing the windowed ground plane 44 and vias 50 connecting the ground plane 44 to the L6 ground plane 24 and the L10 ground plane 48. FIG. 10 is an illustration of L10, showing the solid (i.e. non-windowed) ground plane 48 and vias 50 connecting the ground plane 48 to the L8 ground plane 44.

The embodiments discussed with respect to FIGS. 1-10 are beneficial in that no soldering may be required between PCBs 12 and 14, which means that the RF coupler 2 may be easily separated and reassembled as may need for repair, for example. In addition, low PIM may be achieved which is essential for frequency division duplex (FDD) applications and the capacitive coupling of the ground planes around the broadside coupled lines reduces energy leakage.

In some embodiments, a radio frequency, RF, coupler 2 is configured to carry RF signals from a first printed circuit board 12, PCB, to a second PCB 14. The RF coupler 2 comprises a first trace 16 on an outer surface of the first PCB 12 and a second trace 18 on an outer surface of the second PCB 14. The first trace 16 and the second trace 18 at least partially overlap to form an RF broadside coupler when the first PCB 12 is positioned adjacent the second PCB 14. Each of the first trace 16 and the second 18 trace are covered by respective dielectric coatings 8 and 10 such that a direct current, DC, electrical connection between the first trace 16 and the second trace 18 is prevented when the first PCB 12 is positioned adjacent the second PCB 14.

In one or more embodiments, the first PCB 12 has a multi-layer structure including at least three metal layers and at least two dielectric layers, and the first PCB 12 further comprises a first ground plane 20 on the outer surface of the first PCB 12, the first ground plane 20 defining a metal-free window 22 surrounding the first trace 16; and a second ground plane 40 on a second metal layer of the first PCB 12. The second ground plane 40 extends over the metal-free window 22 of the first ground plane 20 and is separated from the first trace 16 by at least two of the dielectric layers of the first PCB 12. In one or more embodiments, the second metal layer of the first PCB 12 is a second outer surface of first PCB 12. In one or more embodiments, the first PCB 12 further comprises a plurality of vias 42 connecting the first 20 and second ground planes 40 in a region surrounding the metal-free window 22 of the first ground plane 20. In one or more embodiments, the first PCB 12 further comprises at least one windowed ground plane 36 on a metal layer between the first and second ground planes 40, the at least one windowed ground plane 36 having a metal-free window 26 that is coextensive with metal free window 22 of the first ground plane 20. In one or more embodiments, the plurality of vias 42 are further connected to the at least one windowed ground plane 36 between the first 20 and second ground planes 40.

In one or more embodiments, the second PCB 14 has a multi-layer structure including at least three metal layers and at least two dielectric layers, and the second PCB 14 further comprises a third ground plane 24 on the outer surface of the second PCB 14, the third ground plane 24 defining a metal-free window 38 surrounding the second trace 18; and a fourth ground plane 48 on a second metal layer of the second PCB 14. The fourth ground plane 48 extends over the metal-free window 38 of the third ground plane 24 and is separated from the second trace 18 by at least two of the dielectric layers of the second PCB 14. In one or more embodiments, the second metal layer of the second PCB 14 is a second outer surface of second PCB 14. In one or more embodiments, the second PCB 14 further comprises a plurality of vias 50 connecting the third 24 and fourth ground planes 48 in a region surrounding the metal-free window 38 of the third ground plane 24. In one or more embodiments, the second PCB 14 further comprises at least one windowed ground plane 44 on a metal layer between the third 24 and fourth ground planes 48, the at least one windowed ground plane 44 having a metal-free window 46 that is coextensive with metal free window 38 of the third ground plane 24. In one or more embodiments, the plurality of vias 50 are further connected to the at least one windowed ground plane 44 between the third 24 and fourth ground planes 48.

In one or more embodiments, a width of the first trace 16 is selected based at least in part on a desired impedance of the RF broadside coupler. In one or more embodiments, in an overlap area between the first trace 16 and the second trace 18, a width of the second trace 18 is less than the width of the first trace 16. In one or more embodiments, a difference between respective widths of the first 16 and second traces 18 determines a positioning tolerance of the first PCB 12 and the second PCB 14. In one or more embodiments, a length of an overlap area between the first trace 16 and the second trace 18 is selected based on desired performance criteria of the RF broadside coupler. In one or more embodiments, the desired performance criteria of the RF broadside coupler comprises at least one of insertion loss and return loss over a frequency range of interest.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

It will be appreciated by persons skilled in the art that the embodiments described herein are not limited to what has been particularly shown and described herein above. In addition, unless mention was made above to the contrary, it should be noted that all of the accompanying drawings are not to scale. A variety of modifications and variations are possible in light of the above teachings without departing from the scope of the following claims.

1. A radio frequency (RF) coupler configured to carry RF signals from a first printed circuit board to a second PCB, the RF coupler comprising:
a first trace on an outer surface of the first PCB;
a second trace on an outer surface of the second PCB;
the first trace and the second trace at least partially overlapping to form an RF broadside coupler when the first PCB is positioned adjacent the second PCB; and
each of the first trace and the second trace being covered by respective dielectric coatings such that a direct current (DC) electrical connection between the first trace and the second trace is prevented when the first PCB is positioned adjacent the second PCB.

2. The RF coupler claim 2, wherein the first PCB has a multi-layer structure including at least three metal layers and at least two dielectric layers, and wherein the first PCB further comprises:
a first ground plane on the outer surface of the first PCB, the first ground plane defining a metal-free window surrounding the first trace; and
a second ground plane on a second metal layer of the first PCB, the second ground plane extending over the metal-free window of the first ground plane and being separated from the first trace by at least two of the dielectric layers of the first PCB.

3. The RF coupler of claim 2, wherein the second metal layer of the first PCB is a second outer surface of first PCB.

4. The RF coupler of claim 2, wherein the first PCB further comprises a plurality of vias connecting the first and second ground planes in a region surrounding the metal-free window of the first ground plane.

5. The RF coupler of claim 2, wherein the first PCB further comprises at least one windowed ground plane on a metal layer between the first and second ground planes, the at least one windowed ground plane having a metal-free window that is coextensive with metal free window of the first ground plane.

6. The RF coupler of claim 5, wherein the plurality of vias are further connected to the at least one windowed ground plane between the first and second ground planes.

7. The RF coupler of claim 1, wherein the second PCB has a multi-layer structure including at least three metal layers and at least two dielectric layers, and wherein the second PCB further comprises:
a third ground plane on the outer surface of the second PCB, the third ground plane defining a metal-free window surrounding the second trace; and
a fourth ground plane on a second metal layer of the second PCB, the fourth ground plane extending over the metal-free window of the third ground plane and being separated from the second trace by at least two of the dielectric layers of the second PCB.

8. The RF coupler of claim 7, wherein the second metal layer of the second PCB is a second outer surface of second PCB.

9. The RF coupler of claim 7, wherein the second PCB further comprises a plurality of vias connecting the third and fourth ground planes in a region surrounding the metal-free window of the third ground plane.

10. The RF coupler of claim 7, wherein the second PCB further comprises at least one windowed ground plane on a metal layer between the third and fourth ground planes, the at least one windowed ground plane having a metal-free window that is coextensive with metal free window of the third ground plane.

11. The RF coupler of claim 10, wherein the plurality of vias are further connected to the at least one windowed ground plane between the third and fourth ground planes.

12. The RF coupler of claim 1, wherein a width of the first trace is selected based at least in part on a desired impedance of the RF broadside coupler.

13. The RF coupler of claim 1, wherein, in an overlap area between the first trace and the second trace, a width of the second trace is less than the width of the first trace.

14. The RF coupler of claim 1, wherein a difference between respective widths of the first and second traces determines a positioning tolerance of the first PCB and the second PCB.

15. The RF coupler of claim 1, wherein a length of an overlap area between the first trace and the second trace is selected based on desired performance criteria of the RF broadside coupler.

16. The RF coupler of claim 15, wherein the desired performance criteria of the RF broadside coupler comprises at least one of insertion loss and return loss over a frequency range of interest.
